(19) United States
(12) Patent Application Publication
(10) Pub. No.: US 2016/0099213 A1
(43) Pub. Date: Apr. 7, 2016

(54) SEMICONDUCTOR PACKAGE

(71) Applicant: Samsung Electronics Co., Ltd., Suwon-si (KR)

(72) Inventors: Yujung TAE, Seoul (KR); Pyoungwan KIM, Suwon-si (KR)

(21) Appl. No.: 14/721,435

(22) Filed: May 26, 2015

(30) Foreign Application Priority Data
Oct. 2, 2014 (KR) 10-2014-0133266

(51) Int. Cl. H01L 23/538

(52) U.S. Cl. CPC H01L 23/5389

(57) ABSTRACT

A semiconductor package includes a package substrate with a cavity, a plurality of semiconductor chips vertically stacked in the cavity, a first insulating layer on a first surface of the package substrate, a first interconnection layer on the first insulating layer, a second insulating layer on a second surface of the package substrate opposite the first surface, and a second interconnection layer on the second insulating layer.

### CROSS-REFERENCE TO RELATED APPLICATIONS

This U.S. non-provisional patent application claims priority under 35 U.S.C. §119 to Korean Patent Application No. 10-2014-0133266, filed on Oct. 2, 2014, in the Korean Intellectual Property Office, the entire contents of which are hereby incorporated by reference.

### BACKGROUND

Example embodiments of the inventive concepts relate to a semiconductor package, and in particular, to a semiconductor package including a package substrate and a semiconductor chip embedded in the package substrate.

There is an increasing demand for electronic products with light weight, small size, high speed, multi-functionality, high performance, and high reliability. A package technology is one of key technologies needed to satisfy such demand. A chip scale package (CSP) technology, one of recently developed package technologies, allows a semiconductor package to have a small size, such as the size of a semiconductor chip.

Increased capacity of the semiconductor package may also be advantageous. For example, advantages may be achieved by integrating more devices in a given area of each semiconductor chip, which typically requires a new expensive fine-patterning technology (e.g., EUV, DPT, or QPT technology). Accordingly, increasing the capacity of the semiconductor package without using such fine-patterning technology may be desired.

### SUMMARY

Example embodiments of the inventive concepts provide a semiconductor package including a package substrate and vertically-stacked semiconductor chips embedded in the package substrate.

According to example embodiments of the inventive concepts, a semiconductor package may include a package substrate with a cavity, a plurality of semiconductor chips vertically stacked in the cavity, a first insulating layer provided on a first surface of the package substrate, wherein a first interconnection layer is embedded in the first insulating layer, a second insulating layer is provided on a second surface of the package substrate opposite the first surface, wherein a second interconnection layer is embedded in the second insulating layer.

In example embodiments, the semiconductor package may further include an adhesive layer adhesively attaching the plurality of semiconductor chips to each other.

In example embodiments, the adhesive layer may include at least one of polyester, polyethylene, polyethyleneterephthalate, vinyl, polypropylene, polystyrene, polycarbonate, polyvinyl chloride, poly(methyl methacrylate), polyacetal, polyoxymethylene, polybutylene terephthalate, acrylonitrile-butadiene-styrene, or ethylene-vinylalcohol copolymer.

In example embodiments, the semiconductor package may further include a mold layer provided in the cavity to cover the plurality of semiconductor chips.

In example embodiments, the package substrate may include a core portion, a hole, and substrate wirings.

In example embodiments, the hole may be formed to penetrate the package substrate and connect the first surface to the second surface.

In example embodiments, the substrate wirings may be provided on the first and second surfaces and in the hole.

In example embodiments, the plurality of semiconductor chips may be connected to each other through the substrate wirings and the first and second interconnection layers.

In example embodiments, a total thickness of the plurality of semiconductor chips may be substantially equal to or smaller than a thickness of the package substrate.

In example embodiments, the plurality of semiconductor chips may include a first semiconductor chip and a second semiconductor chip stacked along a vertical direction. The first semiconductor chip may include a first active layer adjacent to the first surface and the second semiconductor chip may include a second active layer adjacent to the second surface.

In example embodiments, the first active layer may be connected to the first interconnection layer.

In example embodiments, the second active layer may be connected to the second interconnection layer.

In example embodiments, the semiconductor package may further include a gap-fill insulating layer provided in the cavity.

According to example embodiments of the inventive concepts, a semiconductor package may include first and second interconnection layers vertically spaced apart from each other, a semiconductor chip group between the first and second interconnection layers, a first insulating layer between the first interconnection layer and the semiconductor chip group, and a second insulating layer between the second interconnection layer and the semiconductor chip group. The semiconductor chip group may include a first semiconductor chip and a second semiconductor chip stacked along a vertical direction.

In example embodiments, the semiconductor package may further include an adhesive layer provided between the first and second semiconductor chips.

In example embodiments, the first semiconductor chip may include a first active layer positioned in a top portion thereof, and the second semiconductor chip may include a second active layer positioned at a bottom portion thereof.

In example embodiments, the first semiconductor chip may include a first electrode pad on the first active layer, and the second semiconductor chip may include a second electrode pad on the second active layer.

In example embodiments, the first electrode pad may be connected to the first interconnection layer.

In example embodiments, the second electrode pad may be connected to the second interconnection layer.

In example embodiments, the semiconductor package may further include a mold layer provided to cover the semiconductor chip group.

In example embodiments, the semiconductor package may further include a gap-fill insulating layer provided to cover the semiconductor chip group.

In example embodiments, the semiconductor package may further include a package substrate with a cavity, in which the semiconductor chip group is provided.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A through 1H are sectional views illustrating a method of fabricating a semiconductor package according to example embodiments of the inventive concepts;

FIG. 2 is a sectional view illustrating a semiconductor package according to example embodiments of the inventive concepts;

FIG. 3 is a sectional view illustrating a semiconductor package according to example embodiments of the inventive concepts;

FIG. 4 is a schematic block diagram illustrating a mobile device including a semiconductor package according to example embodiments of the inventive concepts;

FIG. 5 is a schematic block diagram illustrating an electronic system including a semiconductor package according to example embodiments of the inventive concepts;

FIG. 6 is a schematic block diagram illustrating a memory card including a semiconductor package according to example embodiments of the inventive concepts;

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “on,” “connected” or “coupled” to another element, it can be directly on, directly connected or coupled to the other element or intervening elements may be present. In contrast, when an element is referred to as being “directly on,” “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”). Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

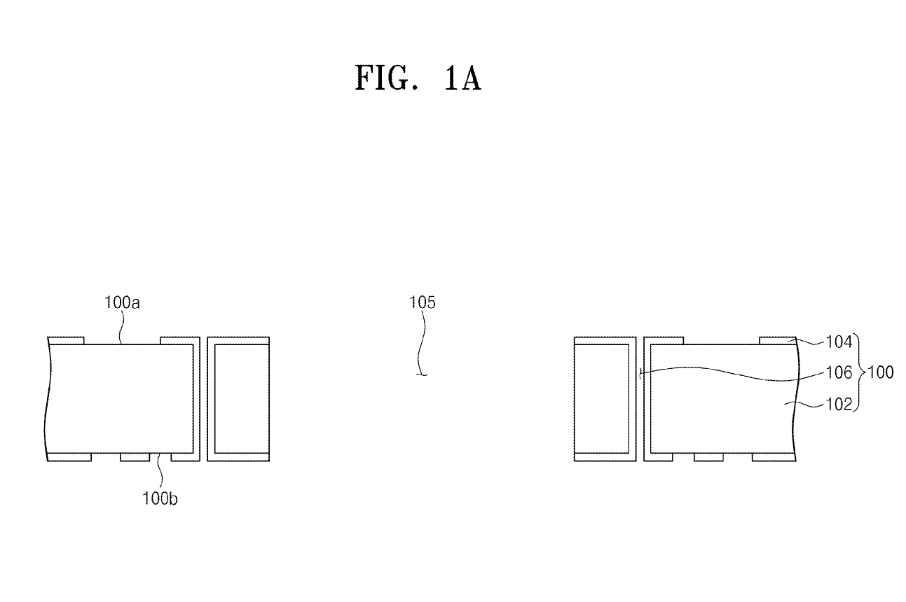

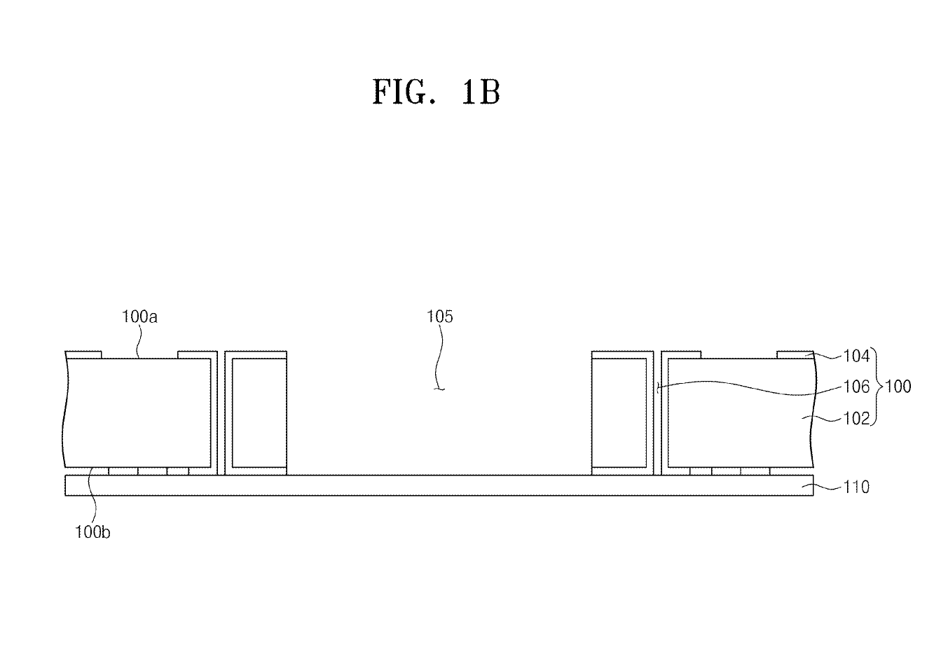

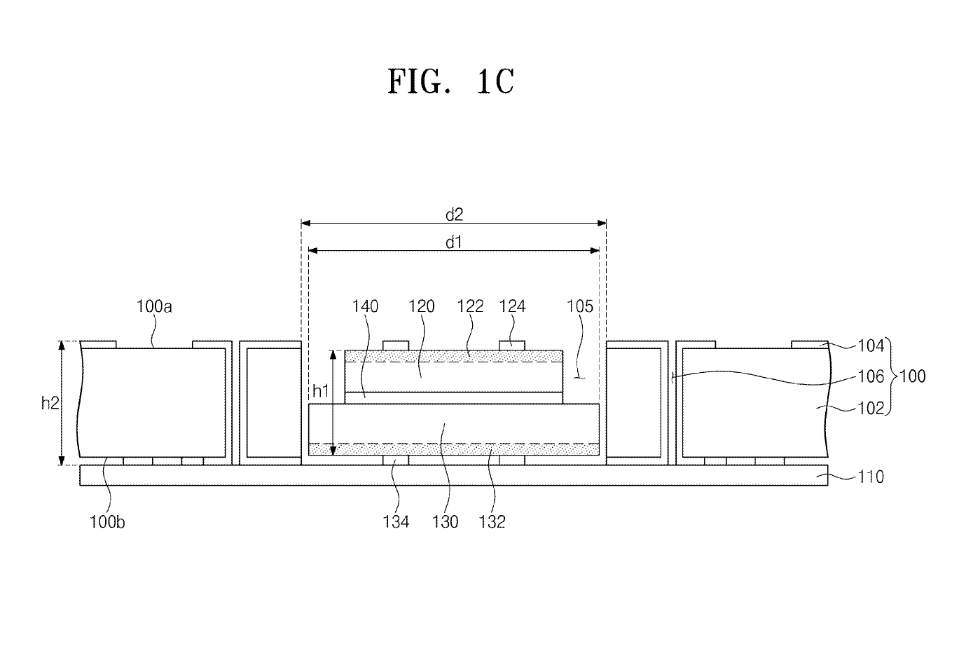

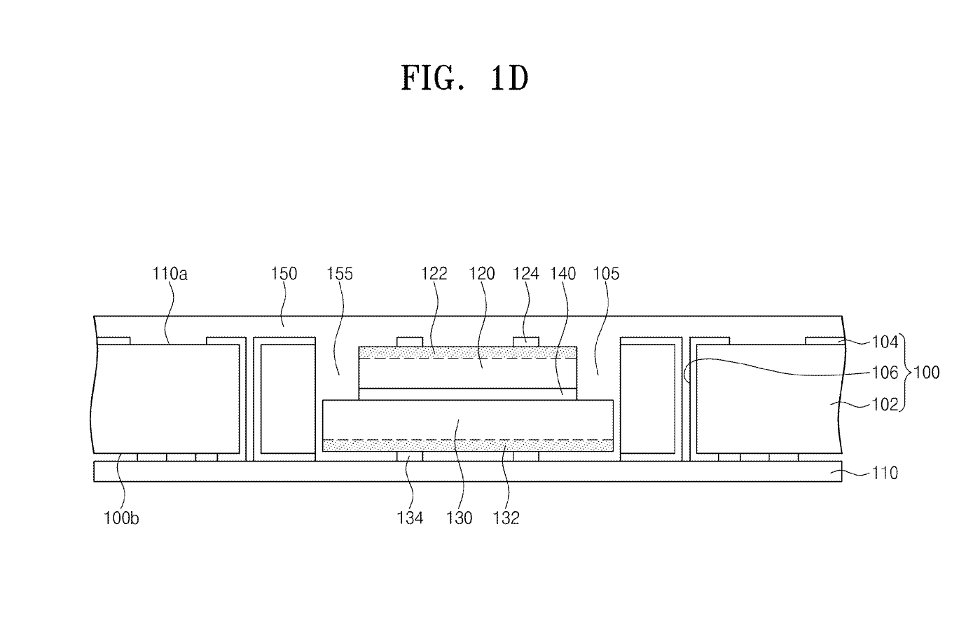

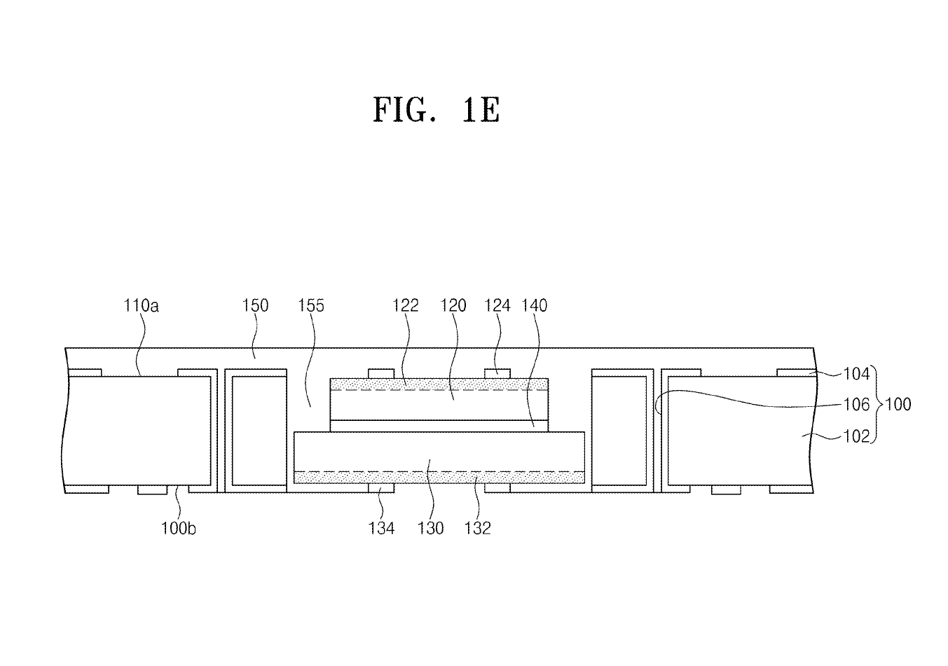

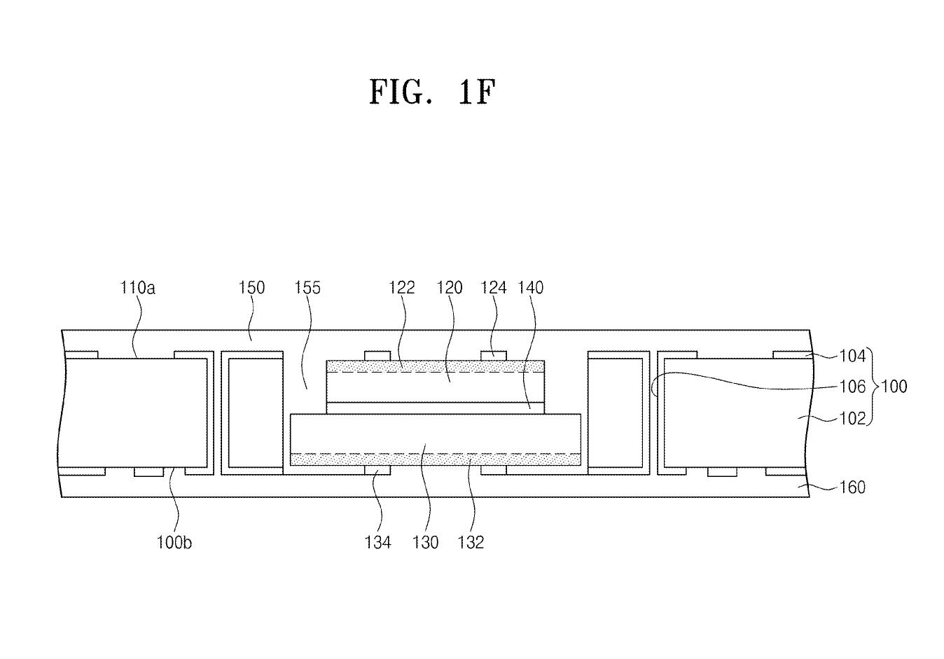

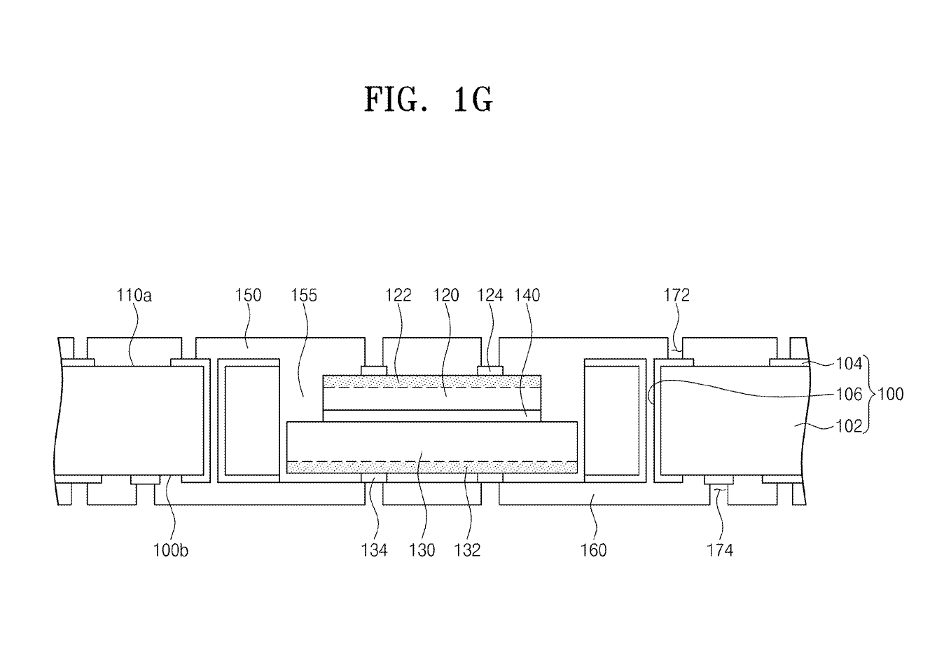

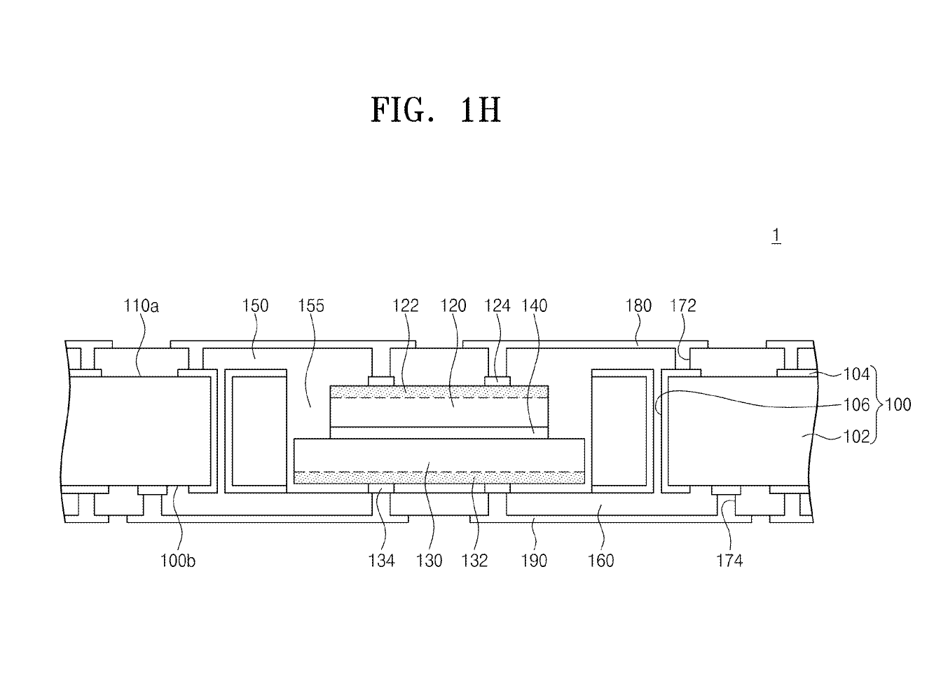

FIGS. 1A through 1H are sectional views illustrating a method of fabricating a semiconductor package according to example embodiments of the inventive concepts.

Referring to FIG. 1A, a package substrate 100 may include a core portion 102, a substrate wirings 104, and a through hole 106. The package substrate 100 may be provided, for example, in the form of a printed circuit board (PCB). The package substrate 100 may have a first surface 100a and a second surface 100b facing each other. For example, the first surface 100a may be a top surface of the package substrate 100, and the second surface 100b may be a bottom surface of the package substrate 100.

The core portion 102 may have the first surface 100a, the second surface 100b, and side surfaces. For example, the core portion 102 may include one of composites composed of a reinforcing element and a resin (e.g., glass fiber/epoxy resin, paper/phenolic resin, or paper/epoxy resin). The through hole 106 may be formed in the core portion 102 to penetrate the package substrate 100. For example, the through hole 106 may be formed to connect the first surface 100a to the second surface 100b.

The substrate wirings 104 may be formed on the first and second surfaces 100a and 100b of the package substrate 100 and/or in the through hole 106. The substrate wirings 104 may partially expose the core portion 102. The substrate wirings 104 may connect the first surface 100a electrically to the second surface 100b. A plurality of insulating layers (not shown) may be further provided to cover the substrate wirings 104. The substrate wirings 104 may include at least one ground line, at least one power line, and at least one signal line. The substrate wirings 104 may be formed of or include, for example, copper. As an example, the substrate wirings 104 may include copper patterns provided in the form of a copper clad laminate.

Although not illustrated in detail, the core portion 102 may include circuit patterns, and the substrate wirings 104 may be electrically connected to the circuit patterns through the internal wirings of the core portion 102. Further, the substrate wirings 104 may include portions electrically connected to each other.

A cavity 105 may be formed to vertically penetrate the package substrate 100. As will be described below, a plurality of semiconductor chips 120 and 130 may be disposed in the cavity 105. The cavity 105 may be formed to have an area larger than the area of the through hole 106.

Referring to FIG. 1B, a supporter 110 may be provided on the second surface 100b of the package substrate 100. The supporter 110 may be configured to, for example, prevent the package substrate 100 from being deformed or bent during the process for fabricating a semiconductor package. In example embodiments, the supporter 110 may be an adhesive film. As an example, the supporter 110 may include a material with an adhesion property that can be changed using UV light or heat applied thereto.

Referring to FIG. 1C, a plurality of semiconductor chips 120 and 130 may be disposed in the cavity 105. The plurality of semiconductor chips 120 and 130 may include a first semiconductor chip 120 and a second semiconductor chip 130 sequentially stacked in a vertical direction. For example, the first semiconductor chip 120 may be stacked on the second semiconductor chip 130. The second semiconductor chip 130 may be provided to have a larger width than the width of the first semiconductor chip 120. Alternatively, the first semiconductor chip 120 may be provided to have a larger width than the width of the second semiconductor chip 130.

The first semiconductor chip 120 may include a first active layer 122 and a first electrode pad 124. The first active layer 122 may be adjacent to the first surface 100a of the package substrate 100. The first active layer 122 may include electronic devices (e.g., a transistor and so forth). The first electrode pad 124 may be on the first active layer 122. For example, the first electrode pad 124 may be formed of or include at least one of silver, palladium, platinum, silver-palladium alloy, nickel, copper, or any combination thereof.

The second semiconductor chip 130 may include a second active layer 132 and a second electrode pad 134. The second active layer 132 may be provided adjacent to the second surface 100b of the package substrate 100. The second active layer 132 may include electronic devices (e.g., a transistor and so forth). The second electrode pad 134 may be provided on the second active layer 132. The second electrode pad 134 may be in contact with the supporter 110. For example, the second electrode pad 134 may be formed of or include at least one of silver, palladium, platinum, silver-palladium alloy, nickel, copper, or any combination thereof.

An adhesive layer 140 may be provided between the first semiconductor chip 120 and the second semiconductor chip 130. For example, the adhesive layer 140 may be a film having an adhesive property. The adhesive layer 140 may be formed of or include at least one of polyester, polyethylene, polyethyleneterephthalate, vinyl, polypropylene, polystyrene, polycarbonate, polyvinyl chloride, poly(methyl methacrylate), polyacetal, polyoxymethylene, polybutylene terephthalate, acrylonitrile-butadiene-styrene, or ethylene-vinylalcohol copolymer. For example, the adhesive layer 140 may include at least one selected from the group consisting of polyester, polyethylene, polyethyleneterephthalate, vinyl, polypropylene, polystyrene, polycarbonate, polyvinyl chloride, poly(methyl methacrylate), polyacetal, polyoxymethylene, polybutylene terephthalate, acrylonitrile-butadiene-styrene, or ethylene-vinylalcohol copolymer. By using the adhesive layer 140, the first semiconductor chip 120 can be adhesively attached to the second semiconductor chip 130, which helps reduce or substantially prevent the first semiconductor chip 120 from being misaligned from the second semiconductor chip 130 in a subsequent process.

In example embodiments, the largest width d1 of the semiconductor chips 120 and 130 may be smaller than a width d2 of the cavity 105. A total thickness h1 of the semiconductor chips 120 and 130 may be smaller than or equal to a thickness h2 of the package substrate 100.

Referring to FIG. 1D, a first insulating layer 150 may be provided on the first surface 100a of the package substrate 100. The first insulating layer 150 may also be provided in the through hole 106 of the package substrate 100. The first insulating layer 150 may be formed of or include, for example, a Resin Coated Copper (RCC) foil, an FR-4, or an ajinomoto build-up film (ABF). The substrate wirings 104 of the package substrate 100 and the semiconductor chips 120 and 130 may be electrically insulated from each other by the first insulating layer 150.

A gap-fill insulating layer 155 may be provided in the cavity 105. The gap-fill insulating layer 155 may cover the semiconductor chips 120 and 130. The semiconductor chips 120 and 130 may be structurally fixed by the gap-fill insulating layer 155 and may be electrically insulated from each other by the gap-fill insulating layer 155. The gap-fill insulating layer 155 may be substantially the same material as the first insulating layer 150.

Referring to FIGS. 1E and 1F, the supporter 110 may be removed from the second surface 100b of the package substrate 100. A second insulating layer 160 may be provided on the second surface 100b of the package substrate 100. For example, the second insulating layer 160 may be formed of or include, for example, a Resin Coated Copper (RCC) foil, an FR-4, or an ajinomoto build-up film (ABF). The substrate wirings 104 of the package substrate 100 may be electrically insulated from each other by the second insulating layer 160.

Referring to FIG. 1G, a first via 172 may be formed in the first insulating layer 150, and a second via 174 may be formed in the second insulating layer 160. The first via 172 may extend in a first direction, and the second via 174 may extend in a second direction. For example, the first direction may be a direction that is substantially normal to the first surface 100a and is oriented outward from the package substrate 100. The second direction may be a direction that is substantially normal to the second surface 100b and is oriented outward from the package substrate 100. In other words, the first and second directions may be antiparallel to each other. The first via 172 and the second via 174 may be formed using, for example, a laser drilling process with yttrium aluminum garnet (YAG) or CO₂ laser. In example embodiments, a plurality of first vias 172 and a plurality of second vias 174 may be formed in the first and second insulating layers 150 and 160, respectively. The first vias 172 may expose the substrate wirings 104 on the first surface 100a and the first electrode pad 124 on the first semiconductor chip 120. The second vias 174 may expose the substrate wirings 104 on the second surface 100b and the second electrode pad 134 on the second semiconductor chip 130.

Referring to FIG. 1H, a first interconnection layer 180 may be formed on the first insulating layer 150 and in the first vias 172, and a second interconnection layer 190 may be formed on the second insulating layer 160 and in the second vias 174. The first interconnection layer 180 may expose a portion of the first insulating layer 150, and the second interconnection layer 190 may expose a portion of the second insulating layer 160.

The first and second interconnection layers 180 and 190 may be formed using a plating or deposition process. The first and second interconnection layers 180 and 190 may be formed of or include, for example, silver (Ag) or copper (Cu). The first interconnection layer 180 may be electrically connected to the substrate wirings 104 and the first electrode pad 124 via the first vias 172. The second interconnection layer 190 may be electrically connected to the substrate wirings 104 and the second electrode pad 134 via the second vias 174. As a result of this example configuration, the first interconnection layer 180 may be electrically connected to the first active layer 122, and the second interconnection layer 190 may be electrically connected to the second active layer 132. The first and second interconnection layers 180 and 190 may be electrically connected to the ground line, the power line and/or the signal line in the core portion 102.

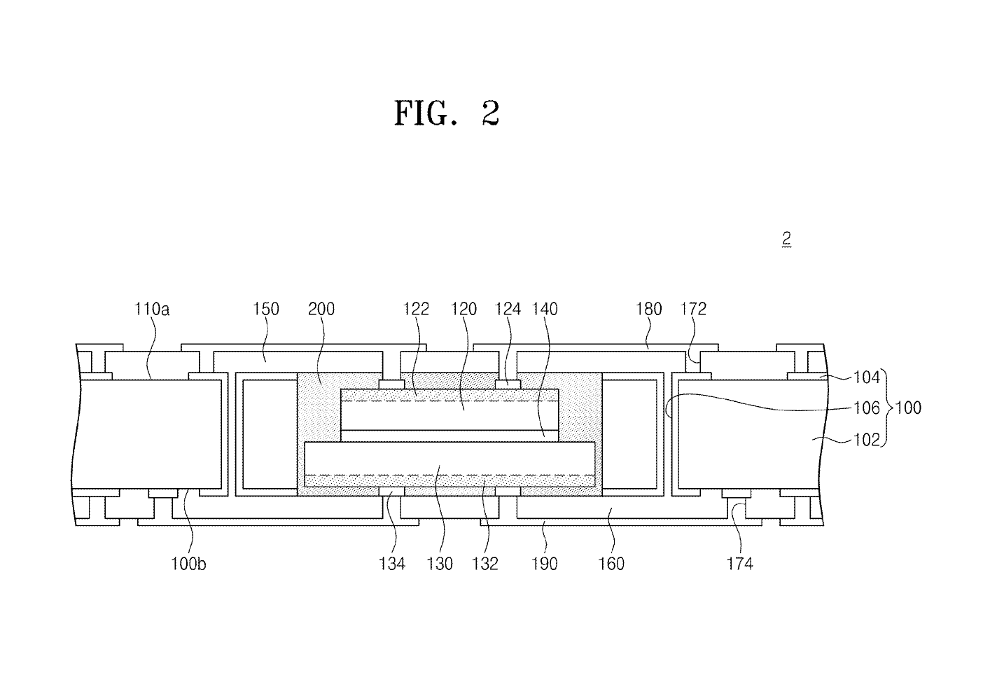

FIG. 2 is a sectional view illustrating a semiconductor package according to example embodiments of the inventive concepts.

Referring to FIG. 2, a mold layer 200 may be formed to cover the plurality of semiconductor chips 120 and 130, for example, before the formation of the first insulating layer 150 or in the step shown in FIG. 1D. In certain embodiments, the mold layer 200 may be formed to expose the first electrode pad 124 and the second electrode pad 134. The mold layer 200 may include, for example, an epoxy molding compound (EMC). The first electrode pad 124 and the second electrode pad 134 may be formed of or include at least one of silver, palladium, platinum, silver-palladium alloy, nickel, copper, or any combination thereof. The mold layer 200 may have substantially the same thickness as the thickness of the package substrate 100. The semiconductor chips 120 and 130 may be structurally fixed by the mold layer 200.

After the formation of the mold layer 200, the first insulating layer 150 may be formed on the first surface 100a. The supporter 110 may be removed to expose the second surface 100b of the package substrate 100, and then, the second insulating layer 160 may be formed on the exposed second surface 100b. The first vias 172 may be formed in the first insulating layer 150, and the second vias 174 may be formed in the second insulating layer 160. Here, the first vias 172 and the second vias 174 may be formed to expose the first and second electrode pads 124 and 134, respectively, in the mold layer 200. The subsequent steps may be performed in substantially the same or similar manner as those of the fabrication method previously described with reference to FIGS. 1A through 1C and FIGS. 1E through 1H.

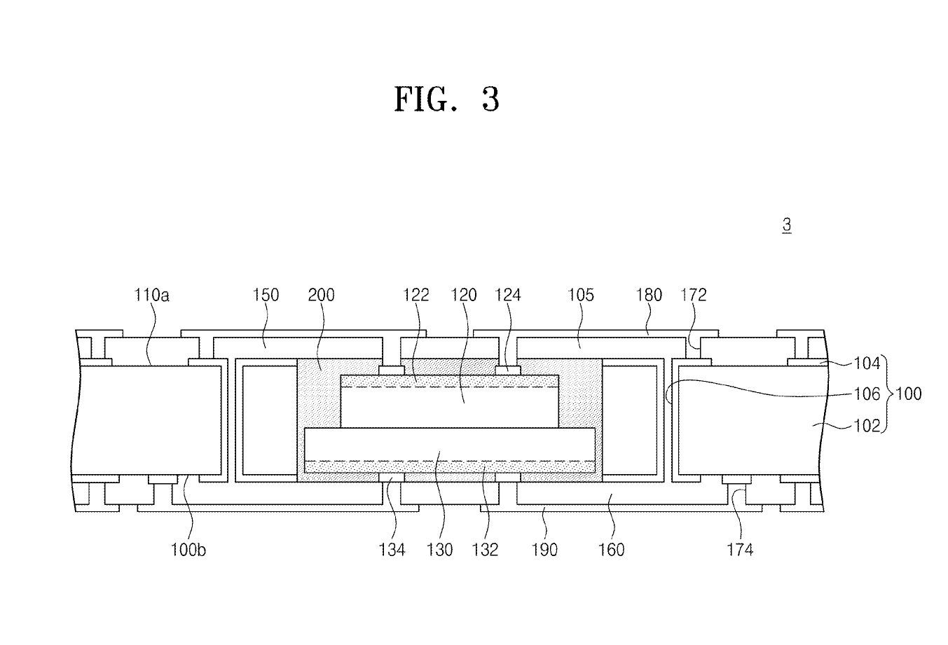

FIG. 3 is a sectional view illustrating a semiconductor package according to example embodiments of the inventive concepts.

Referring to FIG. 3, a plurality of semiconductor chips 120 and 130 may be sequentially stacked in the cavity 105. In the example embodiments described herein, unlike in the example embodiments of FIG. 1D, an adhesive layer such as the adhesive layer 140 illustrated in FIG. 1D, may not be provided between the semiconductor chips 120 and 130. The semiconductor chips 120 and 130 may be disposed in the cavity 105, and the mold layer 200 may subsequently be formed to cover the semiconductor chips 120 and 130. In example embodiments, the mold layer 200 may expose the first electrode pad 124 and the second electrode pad 134. The mold layer 200 may include, for example, an epoxy molding compound (EMC). The first electrode pad 124 and the second electrode pad 134 may be formed of or include at least one of silver, palladium, platinum, silver-palladium alloy, nickel, copper, or any combination thereof. According to example embodiments, the semiconductor chips 120 and 130 may be fixed together by the mold layer 200 instead of an adhesive layer 140. The subsequent steps may be performed in substantially the same or similar manner as the steps of the fabrication method previously described with reference to FIGS. 1A and 1B and FIGS. 1E through 1H.

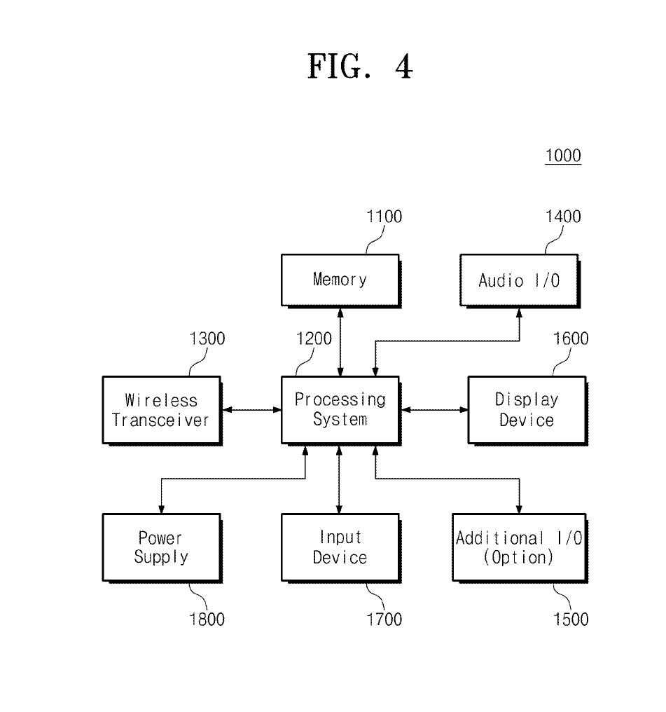

FIG. 4 is a schematic block diagram illustrating a mobile device including a semiconductor package according to example embodiments of the inventive concepts.

Referring to FIG. 4, a mobile device 1000 may include a memory 1100, a processing system 1200, a wireless transceiver 1300, an audio input-output unit 1400, a display device 1600, an input device 1700, and a power supply 1800. The memory 1100 may include a plurality of memory devices. For example, as described in example embodiments of the inventive concepts, the memory 1100 may include two semiconductor chips, allowing for higher memory capacity. Optionally, the mobile device 1000 may further include an additional input-output unit 1500. The processing system 1200 may include at least one of the semiconductor packages according to example embodiments of the inventive concepts. In certain embodiments, the memory 1100 and the memory system 1200 may be stacked to form the semiconductor package according to example embodiments of the inventive concepts. The mobile device 1000 may be used to realize a cellular phone or a tablet computer.

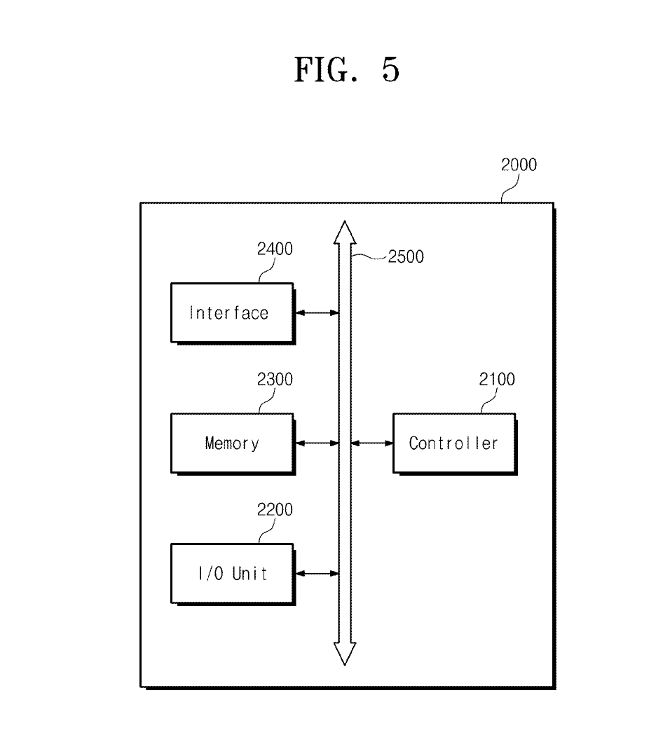

FIG. 5 is a schematic block diagram illustrating an electronic system including a semiconductor package according to example embodiments of the inventive concepts.

Referring to FIG. 5, an electronic system 2000 may include a controller 2100, an input-output unit 2200, and a memory 2300. The controller 2100, the input-output unit 2200, and the memory 2300 may be electrically coupled to each other via a bus 2500, which may serve as a path for exchanging data with each other. The controller 2100 may include, for example, at least one of a microprocessor, a digital signal processor, a microcontroller, or logic devices configured to perform a similar or same function thereto. The controller 2100 and the memory 2300 may include or constitute the package-on-package structure according to example embodiments of the inventive concepts. The input-output unit 2200 may include at least one of a keypad, a keyboard, or a display device. The memory 2300 may be configured to store data therein. For example, the memory 2300 may store data and/or commands to be executed by the controller 2100. The memory 2300 may include a volatile memory device and/or a nonvolatile memory device. For example, the memory 2300 may include a FLASH memory device. In certain embodiments, the FLASH memory device of the memory 2300 may be configured to serve as a semiconductor disk device (SSD). In this case, the usage of the memory 2300 allows the electronic system 2000 to store a large amount of data in a more reliable manner. The electronic system 2000 may further include an interface 2400 for transmitting data to or receiving data from a communication network. The interface 2400 may be provided in a wired or wireless form. For example, the interface 2400 may include an antenna, a wired/wireless transceiver, and so forth. Further, it will be understood by one of ordinary skill in the art that, although not shown, the electronic system 2000 may further include an application chipset, a camera image processor (CIS), an input-output unit, and so forth.

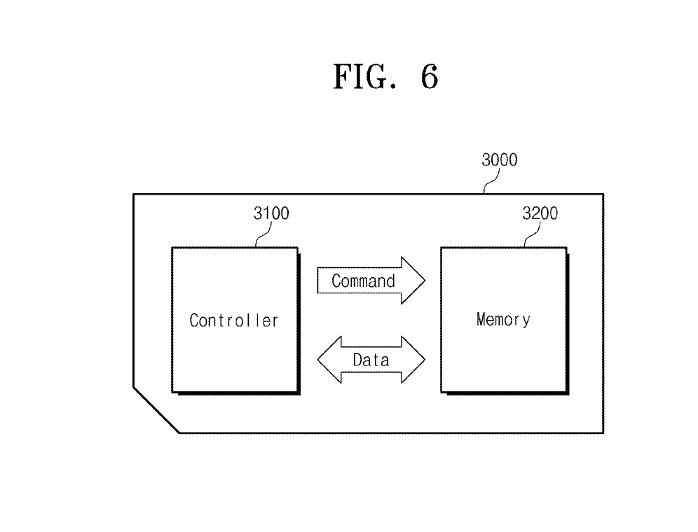

FIG. 6 is a schematic block diagram illustrating a memory card including a semiconductor package according to example embodiments of the inventive concepts.

Referring to FIG. 6, a memory card may include a controller 3100 and a memory 3200 provided in a housing 3000. The controller 3100 and the memory 3200 may be configured to exchange electric signals with each other. For example, under the control of the controller 3100, data may be exchanged between the memory 3200 and the controller 3100. Further, the memory card may be configured to store or read out data in or from the memory 3200.

The controller 3100 and/or the memory 3200 may be provided in the form of a semiconductor package according to example embodiments of the inventive concepts. For example, the controller 3100 may be provided in the form of a system-in-package structure, and the memory 3200 may be provided in the form of a multi-chip-stacking package. In certain embodiments, the controller 3100 and/or the memory 3200 may be provided in the form of a stack-type package. The memory card may be used as a storage media in various portable devices. For example, the memory card may be provided in the form of a multimedia card (MMC) or a secure digital (SD) card.

According to example embodiments of the inventive concepts, a plurality of sequentially-stacked semiconductor chips may be embedded in a package substrate, and thus, it is possible to form interconnection layers on top and bottom surfaces, respectively, of the package substrate.

According to example embodiments of the inventive concepts, in a semiconductor package, the interconnection layers may be connected to the semiconductor chips, without additional connecting element, such as solder balls.

According to example embodiments of the inventive concepts, a plurality of semiconductor chips may be vertically stacked, and thus, it is possible to reduce an area of the semiconductor package.

While example embodiments of the inventive concepts have been particularly shown and described, it will be understood by one of ordinary skill in the art that variations in form and detail may be made therein without departing from the spirit and scope of the attached claims.

1. A semiconductor package, comprising:
a package substrate with a cavity;
a first semiconductor chip and a second semiconductor chip vertically stacked in the cavity;
an insulating layer substantially encapsulating the first semiconductor chip and the second semiconductor chip, the insulating layer including at least one via; and
a plurality of interconnection layers interconnecting the first semiconductor chip and the second semiconductor chip to the package substrate via the at least one via, wherein,
at least one of the plurality of interconnection layers interconnects the first semiconductor chip to a first surface of the package substrate and at least one of the plurality of interconnection layer interconnects the second semiconductor chip to a second surface of the package substrate opposite the first surface.

2. The semiconductor package of claim 1, further comprising:
an adhesive layer configured to adhesively attach the plurality of semiconductor chips to each other.

3. The semiconductor package of claim 2, wherein the adhesive layer comprises at least one of polyester, polyethylene, polyethyleneterephthalate, vinyl, polypropylene, polystyrene, polycarbonate, polyvinyl chloride, poly(methyl methacrylate), polyacetal, polyoxymethylene, polybutylene terephthalate, acrylonitrile-butadiene-styrene, or ethylene-vinylalcohol copolymer.

4. The semiconductor package of claim 1, further comprising:
a mold layer in the cavity, the mold layer being configured to cover the plurality of semiconductor chips.

5. The semiconductor package of claim 1, wherein
the package substrate comprises a core portion, a through hole, and substrate wirings, and
the first surface is connected to the second surface via the through hole.

6. The semiconductor package of claim 5, wherein the substrate wirings are on the first and second surfaces and in the through hole.

7. The semiconductor package of claim 6, wherein the plurality of semiconductor chips are connected to each other through the substrate wirings and the first and second interconnection layers.

8. The semiconductor package of claim 1, wherein a total thickness of the plurality of semiconductor chips is substantially equal to or smaller than a thickness of the package substrate.

9. A semiconductor package, comprising:
first and second interconnection layers vertically spaced apart from each other;
a semiconductor chip group between the first and second interconnection layers;
a first insulating layer between the first interconnection layer and the semiconductor chip group, the first insulating layer including at least one first via; and
a second insulating layer between the second interconnection layer and the semiconductor chip group, the second insulating layer including the at least one second via, wherein,
the semiconductor chip group includes at least a first semiconductor chip and a second semiconductor chip stacked along a substantially vertical direction,
the first semiconductor chip includes a first electrode pad at a top portion thereof and the second semiconductor chip includes a second electrode pad at a bottom portion thereof, and
the first interconnection layer is connected to the first electrode pad via the at least one first via and the second interconnection layer is connected to the second electrode pad via the at least one second via.

10. The semiconductor package of claim 9, further comprising:
an adhesive layer between the first and second semiconductor chips.

11. The semiconductor package of claim 9, wherein the first semiconductor chip includes a first active layer at a top portion thereof, and the second semiconductor chip includes a second active layer at a bottom portion thereof.

12. The semiconductor package of claim 11, wherein the first semiconductor chip includes the first electrode pad on the first active layer, and the second semiconductor chip includes the second electrode pad on the second active layer.

13. (canceled)

14. (canceled)

15. The semiconductor package of claim 9, further comprising:
a mold layer configured to cover the semiconductor chip group.

16. A semiconductor package, comprising:
a plurality of semiconductor chips stacked substantially vertically:
a plurality of interconnection layers at an upper side and a lower side of the plurality of semiconductor chips, one or more of the plurality of interconnection layers being connected to one or more of the semiconductor chips; and
a plurality of insulating layers between one or more of the interconnection layers and one or more of the semiconductor chips, each of the plurality of insulating layers including at least one via, wherein,
at least one of the plurality of interconnection layers being connected to one of the plurality of semiconductor chips via the at least one via.

17. The semiconductor package of claim 16, wherein the plurality of semiconductor chips are in a cavity of the semiconductor package.

18. The semiconductor package of claim 17, wherein:
the plurality of semiconductor chips includes an upper semiconductor chip and a lower semiconductor chip;
the plurality of interconnection layers includes two interconnection layers;
the plurality of insulating layers includes two insulating layers, one of the insulating layers is on a surface of the upper semiconductor chip and another of the insulating layers is on a surface of the lower semiconductor chip; and
each of the interconnection layers is embedded in one of the insulating layers.

19. (canceled)

20. The semiconductor package of claim 16, further comprising:
at least one core portion, at least one through hole and a plurality of substrate wirings, wherein,
an upper surface of the semiconductor package is in contact with a lower surface of the semiconductor package via the at least one through hole.
